(19) United States
(12) Patent Application Publication
(10) Pub. No.: US 2024/0416443 A1
(43) Pub. Date: Dec. 19, 2024

(54) Method for Producing a Solder Connection and Assembly with a Solder Connection

(71) Applicant: Siemens Aktiengesellschaft, München (DE)

(72) Inventors: Christian Walbrecker-Baar, Karlsfeld (DE); Markus Schwarz, Bräunlingen (DE); Stefan Stegmeier, München (DE)

(73) Assignee: Siemens Aktiengesellschaft, München (DE)

(21) Appl. No.: 18/699,944

(22) PCT Filed: Oct. 4, 2022
(86) PCT No.: PCT/EP2022/077550

§ 371 Date: Apr. 10, 2024

(30) Foreign Application Priority Data
Oct. 11, 2021 (EP) 21201813.9

(51) Int. Cl. B23K 1/002; B23K 1/19; B23K 101/36

(52) U.S. Cl. CPC B23K 1/002; B23K 1/19; B23K 2101/36

(57) ABSTRACT

Various embodiments of the teachings herein include a method of establishing a solder bond between a first solder partner and a second solder partner with a solder medium including a metallic solder material and a multitude of magnetic nanoparticles. An example method includes: a) generating a magnetic alternating field with a magnet coil acting on the solder medium; b) heating the magnetic nanoparticles via the interaction with the magnetic alternating field; and c) melting the metallic solder material owing to heat transfer from the magnetic nanoparticles to the metallic solder material and thereby forming the solder bond between the first solder partner and the second solder partner with molten metallic solder material.

### CROSS-REFERENCE TO RELATED APPLICATIONS

This application is a U.S. National Stage Application of International Application No. PCT/EP2022/077550 filed Oct. 4, 2022, which designates the United States of America, and claims priority to EP Application No. 21201813.9 filed Oct. 11, 2021, the contents of which are hereby incorporated by reference in their entirety.

### TECHNICAL FIELD

The present disclosure relates to establishing a solder bond between a first solder partner and a second solder partner by means of a solder medium, wherein the solder medium comprises a metallic solder material which is melted during the method. Various embodiments of the teachings herein include systems and/or methods for producing a solder connection.

### BACKGROUND

Various soldering methods create a solder bond between two or more solder partners. The bonding material may, for example, be a solid solder medium, for example a solder wire or a preform. It is also possible to use a solder paste that can be applied, for example, by a printing method on an interconnect device to be populated. Such solder pastes usually contain a multitude of metallic solder particles and additionally a flux. Irrespective of the respective type of solder medium, the metallic material present therein has to be melted or at least heated to such a degree that diffusion at the interfaces is possible, in order to create the desired solder bond. The heat input required for the purpose, according to the prior art, may be made, for example, via a soldering iron, the flame of a soldering torch, via hot air, hot vapor, thermal radiation, a laser, or electromagnetic induction by means of an inductor.

Many of these heating methods are associated with the drawback that the heat is introduced into the solder partners not just locally at the solder site but in a much greater area, and hence there is the risk of thermal damage to the solder partners. This is particularly true of the soldering iron, the soldering torch, hot air, hot vapor, and thermal radiation. Under some circumstances, a laser can accomplish locally focused heating, but it is often the case that not all areas to be soldered (for example in an electrical assembly) are fully accessible to a laser beam. Even in the case of induction soldering, there is frequently the risk of thermal damage to other electrically conductive elements in the vicinity of the solder site in which unwanted eddy currents are induced.

A further drawback of the heating methods mentioned is that it is difficult to exactly measure and control the temperature attained in the region of the solder site and hence to prevent an excessively high heat input when the temperature required for the creation of the solder bond has been attained. Therefore, it is usually the case that much more heat is introduced than would be necessary for the soldering process, which correspondingly leads to even greater thermal stress on the solder partners or further adjacent components.

### SUMMARY

The teachings of the present disclosure include alternative methods and/or systems of establishing a solder bond that address the drawbacks mentioned. Some embodiments include a soldering method that enables spatially tightly confined heat input in the region of the solder site and advantageously also permits better controllability of limitation of the soldering temperature attained. For example, some embodiments include a method of establishing a solder bond between a first solder partner (10) and a second solder partner (20) by means of a solder medium (100), wherein the solder medium comprises a metallic solder material (110) and a multitude of magnetic nanoparticles (120), wherein the method includes: a) generating a magnetic alternating field (200) with at least one magnet coil (210, 220) and allowing the magnetic alternating field (200) to act on the solder medium (100), b) heating the magnetic nanoparticles (120) via the interaction with the magnetic alternating field (200), and c) melting the metallic solder material (110) owing to heat transfer (300) from the magnetic nanoparticles (120) to the metallic solder material (110) and forming the solder bond between the first solder partner (10) and the second solder partner (20) by means of the molten metallic solder material (110).

In some embodiments, the magnetic nanoparticles (120) are superparamagnetic and comprise a ferromagnetic or ferrimagnetic material, in the form of a metallic alloy or a metal oxide, where the alloy or the metal oxide comprises at least one of the elements iron, cobalt and nickel, and in which the metallic alloy or the metal oxide has a proportion by weight in the overall solder medium of between 1% and 30%.

In some embodiments, the magnetic nanoparticles (120) have a diameter (d120) below 100 nm.

In some embodiments, the magnetic nanoparticles (120) have a Curie temperature within a range between 100° C. and 1200° C., preferably between 150° C. and 400° C.

In some embodiments, the distribution of the Curie temperatures of the individual magnetic nanoparticles (120) has a full width at half maximum (FWHM) of not more than 50° C., or of not more than 30° C.

In some embodiments, the method further comprises d) attaining the Curie temperature of the magnetic nanoparticles (120), such that further heating (300) of the solder medium (100) is avoided.

In some embodiments, the magnetic nanoparticles (120) have a core (121) of a ferromagnetic or ferrimagnetic material and an amagnetic shell (122).

In some embodiments, in step a), at least two magnet coils (210, 220) having different orientation of the magnetic poles are used, and in which the magnet coils (210, 220) are moved relative to the two solder partners (10, 20).

In some embodiments, there is an abrupt interruption of heat transfer (300) and exceedance of a predefined maximum temperature is avoided.

In some embodiments, different solder media (100) having different melting temperatures are used within an assembly (1) for establishment of different kinds of solder bonds.

As another example, some embodiments include an assembly (1) having a first solder partner (10) and a second solder partner (20), wherein the two solder partners (10, 20) are bonded by a solder medium (100) comprising a metallic solder material (110) and a multitude of magnetic nanoparticles (120) embedded therein.

In some embodiments, the magnetic nanoparticles (120) are superparamagnetic and comprise a ferromagnetic or ferrimagnetic material, in the form of a metallic alloy or a metal oxide, where the alloy or the metal oxide comprises at least one of the elements iron, cobalt and nickel, and in which the metallic alloy or the metal oxide has a proportion by weight in the overall solder medium (100) of between 1% and 30%.

In some embodiments, the first solder partner (10) is an electrical interconnect device.

In some embodiments, the second solder partner (20) is an electrical or electronic component, preferably a power electronics component.

### BRIEF DESCRIPTION OF THE DRAWINGS

The teachings of the present disclosure are described hereinafter by a number of working examples with reference to the appended drawings, which show:

FIG. 1: a schematic cross-sectional diagram of a portion of an assembly during the soldering method in a first example method incorporating teachings of the present disclosure;

FIG. 2: a detail of a solder medium for such a solder bond incorporating teachings of the present disclosure;

FIG. 3: a schematic perspective view of a portion of an example assembly together with the magnet coil arrangements used in a soldering method incorporating teachings of the present disclosure; and

FIG. 4: a cross-sectional diagram of an assembly during the establishment of the solder bond in a further example incorporating teachings of the present disclosure.

Identical or functionally identical elements are given the same reference signs in the figures.

### DETAILED DESCRIPTION

The teachings of the present disclosure may be used to establish a solder bond between a first solder partner and a second solder partner using a solder medium. This solder medium comprises a metallic solder material and a multitude of magnetic nanoparticles. An example method comprises: a) generating a magnetic alternating field with at least one magnet coil and allowing the magnetic alternating field to act on the solder medium, b) heating the magnetic nanoparticles via the interaction with the magnetic alternating field, and c) melting the metallic solder material owing to heat transfer from the magnetic nanoparticles to the solder particles and forming the solder bond between the first solder partner and the second solder partner by means of the molten metallic solder material.

This sequence of three method steps a) to c) shows causality of the individual effects: The generation of the magnetic alternating field in step a) firstly brings about the heating of the magnetic nanoparticles in step b), and this heating of the magnetic nanoparticles in turn leads to melting of the solder material in step c), since heat is transferred from the magnetic nanoparticles to the solder material. In some embodiments, steps a) and b) typically proceed simultaneously, and step c) also runs either essentially simultaneously or at least with a time overlap with steps a) and b).

In some embodiments, the solder medium comprises both the magnetic nanoparticles described and the metallic solder material. The melting of the metallic solder material forms the actual solder bond, similarly to the case of a conventional solder paste. The final, mechanically durable solder bond is formed at the moment when the heat input is suppressed or limited, and the solder material solidifies again to give a solid body. Accordingly, the electrical conductivity of the solder bond formed is imparted essentially by the solidified metallic solder material.

The magnetic nanoparticles that are additionally present serve to enable controlled local heat input into the solder medium. These nanoparticles are ferromagnetic or ferrimagnetic. They may thus be periodically magnetized by the magnetic alternating field acting in step a). The size scale of these particles should be in the nanometer range or lower. Because of this small particle size, the magnetization brought about by the magnetic field is not maintained but is transformed to thermal energy by Brownian relaxation and Neel relaxation over a very short timescale.

It is thus possible via the magnetic alternating field acting in step a) to bring about locally confined heating in the zone in which the magnetic nanoparticles are present—in other words locally confined to the region of the solder medium. Thus, the unwanted heating of the solder partners to be bonded and of other adjacent components can be greatly reduced compared to other soldering methods, and reliable melting of the metallic solder component is nevertheless achieved within the soldering zone.

Within the solder medium, the solder material may take the form of metallic solder particles. In some embodiments, the magnetic nanoparticles may be mixed with the metallic solder particles or to be so closely adjacent to these that it is possible overall for there to be heat transfer from the initially heated magnetic nanoparticles to the metallic solder particles, followed by melting of the solder particles. This is the case, for example, in a mixture in which the two types of particle are present alongside one another, where it is particularly the case that the typically significantly smaller magnetic nanoparticles are distributed essentially homogeneously through the gaps between the larger solder particles. In some embodiments, it is also possible that the solder medium contains a multitude of metallic solder particles that each comprise magnetic nanoparticles as delimited inclusions of extrinsic material. In some embodiments, the magnetic nanoparticles may also be embedded into a body of greater extent made of solid solder material, for example distributed through the volume of what is called a preform or a solder wire.

Another example includes an assembly of a first solder partner and a second solder partner. These two solder partners are bonded by a solder bond comprising a metallic solder component and a multitude of magnetic nanoparticles embedded therein. This solder bond may be established by the methods described herein, recognizable by the presence of the embedded magnetic nanoparticles. By contrast with the metallic solder material, the magnetic nanoparticles do not melt in the establishment of the solder bond but are still preserved as nanoscale inclusions in the solidified solder medium. The benefits of the assemblies of the described herein are apparent in an analogous manner to the above-described benefits of the methods.

In some embodiments, the magnetic nanoparticles may be superparamagnetic. In other words, the nanoparticles comprise a ferromagnetic or ferrimagnetic material, and in the case of these particles, after a previously active external magnetic field is switched off, no lasting magnetization is maintained even below the Curie temperature. This effect occurs because of the small particle size, although the minimum particle size for this purpose is also dependent on the respective material. It is generally advantageous in this connection, however, when the magnetic nanoparticles have a diameter of 100 nm or less. In the case of nonspherical particles, rather than the diameter, the maximum external dimension should be used here. A generally advantageous range for the typical particle size is, for example, between 10 nm and 50 nm, or between 10 nm and 25 nm. In the case of magnetic nanoparticles of the size scale described, energy from the active magnetic alternating field can be converted particularly efficiently to heating of the nanoparticles by Brownian and Neel relaxation.

In some embodiments, the magnetic nanoparticles have a Curie temperature within a range between 100° C. and 1200° C., or between 150° C. and 400° C. In some embodiments, all the magnetic nanoparticles present have a Curie temperature within the range specified. This means that the Curie temperature can be matched to the temperature range of the soldering process used. In particular, the Curie temperature of the magnetic nanoparticles is above the melting temperature or above the melting range of the metallic solder material. In this way, it is possible to achieve the effect that the magnetic nanoparticles can be heated in the active magnetic alternating field to a sufficiently high temperature to cause the solder material to melt.

However, when the temperature of the magnetic nanoparticles exceeds the Curie temperature, further heating of the solder medium is prevented since essentially no heat input from the energy of the magnetic field into the magnetic nanoparticles takes place above that temperature. There is thus automatic shutdown of heat input in the region of the Curie temperature of the nanoparticles, by means of which it is possible to avoid excessive thermal stress. In particular, in the case of this method, heat input is thus not just concentrated locally on the region of the solder medium; instead, it is also possible to limit the maximum temperature to a range advisable for the particular use via suitable choice of the nanoparticle material.

The Curie temperature of the nanoparticles is sensitive to the exact composition of the ferromagnetic or ferrimagnetic material present, such that it is also possible via the choice of material to specifically choose the temperature at which the automatic shutdown mechanism kicks in. It is thus possible for the achievable maximum temperature of the solder medium to be matched not just to the melting temperature of the metallic solder material but appropriately also to the thermal durability of the solder partners and of any other elements present in the assembly.

It is thus also possible for the assembly to include thermally sensitive elements, for example a housing and/or an insulation layer of a heat-sensitive polymer. The locally confined heating and the automatic limitation thereof makes it possible to avoid damage thereby in the soldering process, and the metallic solder material can nevertheless reliably be made to melt. It is also possible here for the magnetic alternating field required for heating to penetrate through other elements that are themselves barely heated in the soldering process since they have a low level of interaction with the magnetic field. For instance, it is possible to enable soldering in overall systems and through components, and even a soldering process within a liquid or through a liquid.

In some embodiments, the distribution of the Curie temperatures of the individual magnetic nanoparticles is comparatively narrow. They may thus be what are called CNPs (Curie temperature tuned magnetic nanoparticles). Such CNPs are described, for example, in the publication by R. Chaudhary, V. Chaudhary, R. V. Ramanujan, T. W. J. Steele “Magnetocuring of temperature failsafe epoxy adhesives” in Applied Materials Today 21 (2020) 100824.

In some embodiments, the distribution of the Curie temperatures of the individual magnetic nanoparticles has a full width at half maximum (FWHM) of not more than 50° C., or of not more than 30° C. When the Curie temperatures of the individual nanoparticles are so closely matched, the above-described automatic confinement of heat input works within a particularly precisely defined temperature window. The method may then accordingly comprise d) attaining the Curie temperature of the magnetic nanoparticles, such that further heating of the solder medium is avoided.

In other words, the attainment of the Curie temperature of the nanoparticles leads to an abrupt interruption of heat input. Thus it is possible to particularly reliably avoid the exceedance of a predefined maximum temperature and hence also avoidance of thermal damage to adjacent elements. In some embodiments, it is also possible here to dispense with a complex sensor system for temperature detection and an additional closed-loop control device for avoidance of overheating.

In some embodiments, the magnetic nanoparticles comprise a ferromagnetic or ferrimagnetic material which is in the form of a metallic alloy or a metal oxide. In some embodiments, this alloy or metal oxide comprises at least one of the elements iron, cobalt, and nickel. It is possible here for the metal oxide to be a mixed oxide, for example a compound of the MnₓZn₁₋ₓFe₂O₄ type where x may in particular assume values between 0.4 and 0.7. The establishment of a precisely defined Curie temperature is described for this type of compound in the above-cited paper by R. Chaudhary et al.

In some embodiments, such a metallic alloy or metal oxide has a proportion by weight in the overall solder medium of between 1% and 30%. A proportion by weight of at least 1% is appropriate in order to bring about sufficient heat input into the solder medium via the nanoparticles, which in turn leads to melting of the metallic solder material. On the other hand, an excessively high proportion by weight above 30% is generally inappropriate since the mechanical and electrical properties of the solder bond are then too significantly impaired. Therefore, the proportion by weight, with regard to a particularly good electrical conductivity of the solder bond, may be limited to not more than 10%. If, however, the key factor is the creation of a permanent mechanical bond and electrical conductivity is of minor importance, the proportion by weight of the magnetic nanoparticles may then quite possibly be in the upper portion of this range, i.e. between 10% and 30%.

In some embodiments, the magnetic nanoparticles may have a core of a ferromagnetic or ferrimagnetic material and an amagnetic shell. An amagnetic material shall be understood here to mean a material which is at least not ferro- or ferrimagnetic. Thus, the shell may be formed, for example, from an organic material and may include, for example, oleic acid and/or a bisphenol A diglycidyl ether. But inorganic materials are also useful for the shell, for example silicon dioxide (SiO₂) or graphene. Such a shell may in particular serve for colloidal stabilization of the magnetic nanoparticles. In other words, they prevent agglomeration of the particles, which can be triggered, for example, by the influence of moisture. For this purpose, the thickness of such a colloidally stabilizing shell may, for example, be within a range between 2 nm and 10 nm. Such a thin shell may be sufficient to prevent agglomeration of the nanoparticles to form larger clusters and, accordingly, to enable a fine and approximately homogeneous distribution of the nanoparticles throughout the solder medium. It is thus possible to achieve particularly uniform heating of the overall solder medium.

In some embodiments, it is also possible in principle to use uncoated magnetic nanoparticles. It may be possible here to accept formation of clusters of such nanoparticles. Particularly when a particle mixture of magnetic nanoparticles and metallic solder particles is used, the size scale of the agglomerates formed is in the region of the size scale of the solder particles used or lower. It is then possible, in spite of the agglomeration of the nanoparticles, to provide a solder medium which is homogeneous enough to enable uniform heat transfer from the magnetic nanoparticles to the metallic solder particles.

In some embodiments, the solder medium may be a solder paste. Such a solder paste may in particular comprise a mixture of magnetic nanoparticles and metallic solder particles. Such solder particles may be essentially spherical and have a diameter in the range between 1 μm and 160 μm, or between 2 μm and 50 μm. This corresponds to the customary particle diameter in typical conventional solder pastes with comparatively fine solder particles.

In some embodiments, the solder medium may be a solid solder molding, also referred to in the specialist field as a preform. Such a solder preform may, for example, be a solder ring or else may take the form of a disk, of a tape, of a flat rectangle or of a horseshoe. In some embodiments, it is also possible to use a solder wire or another solid solder element.

In general, and regardless of whether it is a solder paste comprising solder particles or a solder preform, the solder material may be a low-melting alloy, for example a soft solder, a hard solder, or a high-temperature solder. All standard solder alloys are suitable in principle for the solder material, in particular alloys with tin, bismuth, silver, copper, zinc, lead, and/or antimony.

In addition to the solder material and the magnetic nanoparticles, the solder medium may generally include a flux. This is also true regardless of whether, for example, a solder paste or a solid solder preform is involved. All standard materials are also useful for the flux. For example, the flux may be a resin, an oil, a solvent, a salt or water, or comprise such a compound as a constituent. Overall, the solder medium is a mixture of materials that may also comprise further optional components in addition to the solder material, the magnetic nanoparticles, and the optional flux.

In some embodiments, at least two magnet coils having a different orientation of the magnetic poles may be used in step a). In this execution variant, two superposed magnetic alternating fields are thus generated, with superposition of the regions of high magnetic flux density in a focus region. In this variant, even greater focusing of the local heating into a tightly confined region is brought about than would be possible with just one magnet coil or with just one magnetic pole direction. The size of the focus region may be quite different depending on the application: For instance, for solders of surface mount devices or ball grid arrays, the focus size may be in the sub-millimeter range. For large-area solder regions, for example in the rail engineering sector or for soldering of pipes, the focus size may alternatively be significantly greater and even be in the meter range.

In some embodiments, focusing of the magnetic field can also be achieved by means of one or more flow-guiding elements. For example, it is possible to arrange two tapering iron cores on either side of the solder site in order to focus the magnetic field to a focus region of suitable size.

In general, and regardless of the number and spatial arrangement of the magnet coils used, the frequency of the magnetic alternating field may be in the region of a few hundreds of kHz, preferably between 100 kHz and 1000 kHz and, for example, in the region of about 400 kHz. In the case of a frequency in such a range, the corresponding relaxation processes in the magnetic nanoparticles can achieve an efficient heat input into the solder medium.

In some embodiments, the at least one magnet coil may be moved relative to the two solder partners during the soldering method. It is immaterial here whether the solder partners are fixed and the at least one magnet coil is moved or vice versa. The overall result in this embodiment is in any case translational relative movement, such that the focus region or region of maximum energy input is moved across the assembly in question and hence specific local melting of the solder medium at different successive positions is enabled. This execution variant of the method also enables a progression in which the respective active solder zone is moved outward from a region inside the assembly (or else of course vice versa). It is thus possible by this variant, particularly when the position of maximum energy input is spatially tightly confined, also to create individual local solder sites within a complex assembly, and subsequent repair of such inner locally confined solder sites may also be possible. A repair may comprise, for example, exchange of components and also melting and repositioning of incorrectly positioned components that have already been soldered on. In some embodiments, the type of heat input described also enables subsequent locally confined heat treatment for dissipation of stress in already created solder bonds.

In some embodiments, different solder media having different melting temperatures may be used within an assembly for establishment of different kinds of solder bonds. The soldering methods described herein are then used for at least one type of these solder bonds. In the case of the other types of solder bonds, it is then possible either also to use this method of the invention with another solder medium, or it is possible to use a conventional soldering method with one or more other solder bonds. For example, it is possible to use a different method for an SMD solder bond than for the soldering-on of a plug or a load contact. It is also possible to use different soldering methods for the soldering of bonds for high-frequency, high-current and/or high-voltage applications than for lower-frequency, -current or -voltage ranges. Finally, it is also possible to use a different method for particular materials, for example a lead-containing solder, than, for example, for a lead-free solder elsewhere in the assembly.

In some embodiments, the assembly of the invention may be an electronics assembly and in particular a power electronics assembly having one or more power electronics components. It is here that the benefits of the teaching may be particularly manifested, since the key factor here is usually the creation of a reliable and highly electrically conductive solder bond, but there is on the other hand also a need to protect further elements within the same assembly from excess thermal stress.

In some embodiments, the assembly at least comprises at least one solder bond established by the methods described herein. This solder bond can appropriately form an electrically conductive connection between the corresponding solder partners.

In some embodiments, the first solder partner may be an electrical interconnect device. It may thus, for example, be a printed circuit board or a ceramic interconnect device. In any case, this interconnect device may form the mechanical and/or electrical basis of the assembly by which the further elements are borne. Accordingly, one or more further elements that then form the second and optional further solder partners may be soldered onto this interconnect device by the method of the invention.

In some embodiments, the second solder partner may be an electrical or electronic component. This is also true of further solder partners that are optionally present. In particular, an interconnect device may be populated with one or more such components and may have been bonded to these by the soldering methods described herein. It is generally advantageous here to provide an electrically conductive connection by which the component in question is indeed electrically contacted. Such a component may, for example, be an IGBT, a diode, a MOSFET, a thyristor, a shunt, or a capacitor.

However, the solder partners need not necessarily be an electrical interconnect device and an electrical component. It is also possible for any other components, for example a pipe or a machine housing, to form the first solder partner, and it is possible for any other components to form the second solder partner. For example, a sensor (in particular for temperature or mechanical stresses) may be soldered onto a pipe or machine housing. In some embodiments, the soldering technique may also be used in the field for repairs, for example in order to solder multiple pipe parts to one another.

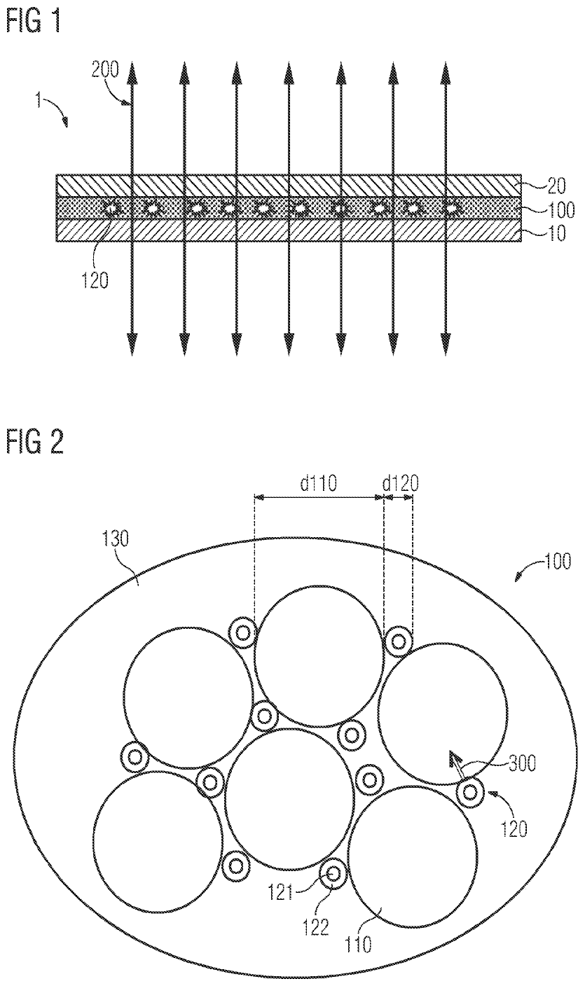

For instance, FIG. 1 shows a portion of an assembly 1 in a first example method incorporating teachings of the present disclosure in a schematic cross section. In the detail of this assembly 1 shown, the method produces a solder bond between a first solder partner 10 and a second solder partner 20. These may in principle be any elements of the assembly that can be permanently mechanically bonded by soldering. It may also be possible here to create a bond of good electrical conductivity and hence electrical contact connection of the two solder partners 10 and 20. The solder bond to be established is imparted here by a solder medium 100 which firstly comprises a metallic solder material as a component and additionally comprises a multitude of magnetic nanoparticles 120 embedded into the solder medium 100. The solder medium 100 may in principle be configured in different ways. It may, for example, be a solder paste or else a solid solder preform. In each case, the magnetic nanoparticles 120 are distributed through the volume of the solder medium. In the example of FIG. 1, the solder medium 100 may in particular be a solder paste including a particle mixture of metallic solder particles and magnetic nanoparticles.

In order to form the solder bond between the two solder partners 10 and 20, a magnetic alternating field 200 is created, as indicated in FIG. 1 by corresponding double-headed arrows. This magnetic alternating field affects the region of the solder medium 100. In particular, magnetic interaction takes place with the magnetic nanoparticles 120 present therein, which leads to heating of these nanoparticles. The magnetic nanoparticles embedded into the solder medium 100 thus become local heat sources within the solder medium 100 under the action of the magnetic alternating field 200, from which heat is transferred to the other components of the solder medium. This heat input, which is very local and confined essentially to the region of the solder medium 100, causes the metallic solder material in the solder medium to melt. After the magnetic alternating field has been switched off, the solder medium is cooled and this melt is correspondingly solidified, which forms a permanent solder bond between the two solder partners 10, 20.

When the local heating of the magnetic nanoparticles results in exceedance of the Curie temperature thereof, this results in an automatic interruption of the heat input into the solder medium. The temperature attained is thus automatically limited. By virtue of this effect, in conjunction with the locally confined heating zone, the method is therefore a particularly gentle soldering method in which thermal damage of further elements of the assembly that are optionally present may be avoided. Heat input into the two solder partners 10 and 20 to be bonded is also relatively low.

FIG. 2 shows a detail in the region of a solder medium 100 as can be used, for example, in the soldering method of FIG. 1. Here too, the solder medium 100 is a solder paste having a multitude of metallic solder particles 110. These take the form here of approximately spherical solder spheres composed of a comparatively low-melting metallic alloy. The diameter d110 thereof may, for example, be in the region of a few micrometers to a few tens of micrometers. As well as these metallic particles, the paste also comprises a multitude of magnetic nanoparticles 120, as already described above. In addition, the solder paste in this example also comprises an (optional) organic flux 130. The diameter d120 of the magnetic nanoparticles 120 is significantly smaller than the diameter d110 of the metallic solder spheres 110. The size scale of the magnetic nanoparticles 120 is in the region of 100 nm or lower. These nanoparticles contain a ferromagnetic or ferrimagnetic material component. Because of the small particle size, the nanoparticles are superparamagnetic overall. This property enables significant local heating of the magnetic nanoparticles in the magnetic alternating field and hence the energy input required for the soldering method into the solder medium 100. As indicated by the illustrative arrow 300, heat transfer also takes place here from the nanoparticles 120 to the metallic solder particles 110, as a result of which they are melted.

In the example of FIG. 2, the magnetic nanoparticles have two material components, namely a core 121 of a ferromagnetic or ferrimagnetic material and an amagnetic shell 122. This is not absolutely necessary, and the nanoparticles may alternatively also consist solely of a uniform ferro- or ferrimagnetic material. But the core-shell structure shown may be advantageous since coating with the shell material can in particular avoid excessive agglomeration of the individual nanoparticles.

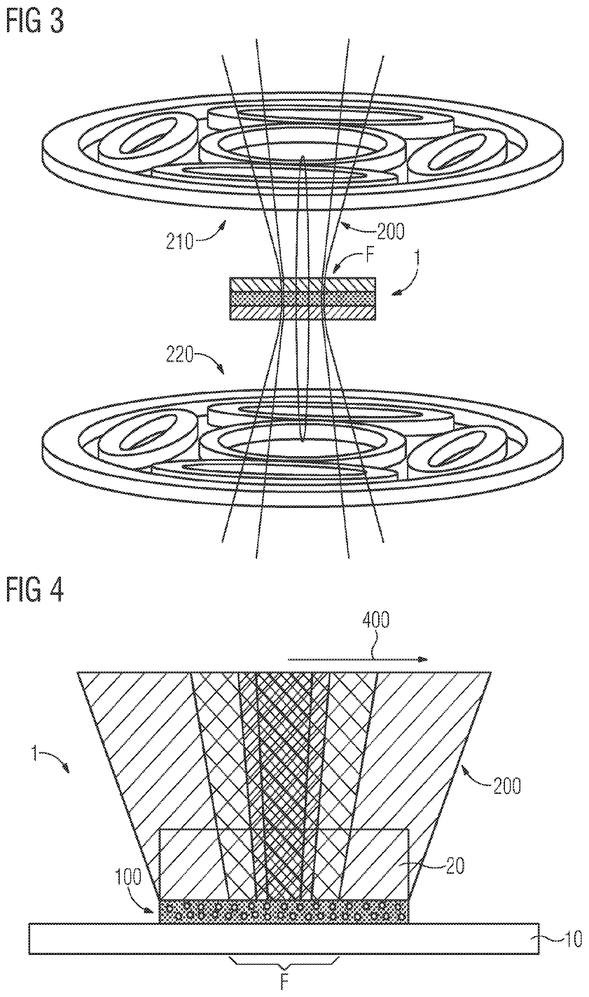

FIG. 3 shows a schematic partial perspective view of a portion of an assembly 1, positioned in the focus region F of a magnetic alternating field 200 for performance of one or more of the methods described herein. Otherwise, the assembly 1 may be of a similar design to that in the example of FIG. 1 and may in particular comprise a similar solder medium 100 for formation of the solder bond. The focus region F may be comparatively narrow, such that the energy input into the solder medium is spatially tightly confined.

In order to achieve this, two magnet coil arrangements 210 and 220 are provided here to create the magnetic alternating field 200. In this example, they are present on opposite sides of the assembly, such that the assembly 1 is in the middle between the two coil arrangements. In this example, the magnetic poles of the two coil arrangements 210 and 220 are coaxial to one another. Alternatively, it is also possible that two or more magnet coils with different orientations of the corresponding magnetic poles are used. In particular, the magnetic poles may then cross in the focus region F, which under some circumstances permits even stronger focusing of the energy input.

FIG. 4 shows a cross-sectional diagram of a further assembly 1, in which a solder bond is again created by a method incorporating teachings of the present disclosure. In this example, the first solder partner is an electrical interconnect device 10, and the second solder partner is an electronic component 20. In particular, the second solder partner is a semiconductor chip that has been placed onto the interconnect device and is to be bonded in an electrically conductive manner to conductor tracks on the interconnect device 10 by the soldering method. Here too, there is a solder medium 100 between the two solder partners 10 and 20, comprising, similarly to the previous examples, a metallic solder component and magnetic nanoparticles distributed through the solder medium 100.

Here too, a magnetic alternating field 200 acts on the solder region, again forming a relatively narrow focus region F in which the energy input from the magnetic field 200 is sufficiently high to cause the metallic solder component to melt. In particular, the lateral extent of the focus region is less than the lateral extent of the chip, such that point local melting of the solder medium 100 is possible in a subregion beneath the chip. The arrow 400 indicates that, during the soldering method, relative movement is performed between the magnetic alternating field (or the magnetic field-generating coil arrangement) on the one hand and the assembly 1 on the other hand. This allows the heated solder region to be confined quite specifically to a narrow subregion of the assembly. Moreover, FIG. 4 illustrates that the magnetic alternating field can also penetrate through the chip 20 and/or other elements of the assembly without bringing about significant heating in these elements, since the main energy input is confined to the region of the solder medium 100 with the magnetic nanoparticles.

### LIST OF REFERENCE SIGNS

1 assembly
10 first solder partner (interconnect device)
20 second solder partner (component)
100 solder medium
110 metallic solder material (solder particles)
120 magnetic nanoparticles
121 core
122 shell
130 flux
200 magnetic alternating field
210 first magnet coil arrangement
220 second magnet coil arrangement
300 heat transfer
400 relative movement
d110 diameter of the metallic solder particles
d120 diameter of the magnetic nanoparticles
F focus region

What is claimed is:

1. A method of establishing a solder bond between a first solder partner and a second solder partner with a solder medium including a metallic solder material and a multitude of magnetic nanoparticles, the method comprising:
a) generating a magnetic alternating field with a magnet coil acting on the solder medium;
b) heating the magnetic nanoparticles via the interaction with the magnetic alternating field; and
c) melting the metallic solder material owing to heat transfer from the magnetic nanoparticles to the metallic solder material and thereby forming the solder bond between the first solder partner and the second solder partner with molten metallic solder material.

2. The method as claimed in claim 1, wherein:
the magnetic nanoparticles are superparamagnetic and comprise a ferromagnetic or ferrimagnetic material comprising at least one of the elements: iron, cobalt; and nickel, and
the ferromagnetic or ferrimagnetic material has a proportion by weight in the overall solder medium of between 1% and 30%.

3. The method as claimed in claim 1, wherein the magnetic nanoparticles each has a diameter below 100 nm.

4. The method as claimed in claim 1, wherein each of the magnetic nanoparticles has a Curie temperature within a range between 100° C. and 1200° C.

5. The method as claimed in claim 1, wherein a distribution of Curie temperatures of individual magnetic nanoparticles has a full width at half maximum of not more than 50° C.

6. The method as claimed in claim 1, further comprising
d) attaining a Curie temperature of the magnetic nanoparticles such that further heating of the solder medium is avoided.

7. The method as claimed in claim 1, wherein the magnetic nanoparticles each have a core of a ferromagnetic or ferrimagnetic material and an amagnetic shell.

8. The method as claimed in claim 1, wherein, step a), at least two magnet coils having different orientation of the magnetic poles are used, and the magnet coils are moved relative to the two solder partners.

9. The method as claimed in claim 8, further comprising abruptly interrupting heat transfer and avoiding exceedance of a predefined maximum temperature by movement of the at least two magnet coils.

10. The method as claimed in claim 1, further comprising using multiple solder media having different melting temperatures within an assembly to establish different kinds of solder bonds.

11. An assembly comprising:
a first solder partner; and
a second solder partner;
wherein the two solder partners are bonded by a solder medium comprising a metallic solder material and a multitude of magnetic nanoparticles embedded therein.

12. The assembly as claimed in claim 11, wherein the magnetic nanoparticles are superparamagnetic and comprise a ferromagnetic or ferrimagnetic material comprising at least one of the elements iron, cobalt, and nickel, and material has a proportion by weight in the overall solder medium of between 1% and 30%.

13. The assembly as claimed in claim 11, wherein the first solder partner comprises an electrical interconnect device.

14. The assembly as claimed in claim 11, wherein the second solder partner comprises an electrical or electronic component.
